(19) United States
(12) Patent Application Publication
(10) Pub. No.: US 2010/0295615 A1
(43) Pub. Date: Nov. 25, 2010

(54) CML OUTPUT DRIVER

(75) Inventors: Dirk Muentefering, Wedemark (DE); Andreas Bock, Isernhagen (DE)

Correspondence Address: TEXAS INSTRUMENTS INCORPORATED, P O BOX 655474, M/S 3999, DALLAS, TX, 75265, US

(73) Assignee: Texas Instruments Deutschland GmbH, Freising (DE)

(21) Appl. No.: 12/764,236

(22) Filed: Apr. 21, 2010

(30) Foreign Application Priority Data
Apr. 23, 2009 (DE) 10 2009 018 696.4

(51) Int. Cl. H03F 3/45

(52) U.S. Cl. 330/252

(57) ABSTRACT

An integrated circuit (IC) for driving a light emitting semiconductor device is provided. The IC includes an input stage configured to receive a first input signal with a first differential pair of bipolar transistors and a second input signal with a second differential pair of bipolar transistors and to provide a pre-driver output signal being a superposition of the first input signal and the second input signal and an output stage including a third differential pair of bipolar transistors for receiving the pre-driver output signal of the input stage and for driving the light emitting semiconductor device in response to the pre-driver output signal, wherein the IC is configured to pre-distort the pre-driver output signal of the input stage so as to compensate a signal distortion of the output stage.

### CROSS-REFERENCE TO RELATED APPLICATIONS

This application claims priority from German Patent Application No. 10 2009 018 696.4, filed Apr. 23, 2009, which is hereby incorporated by reference for all purposes.

### FIELD OF THE INVENTION

The invention relates to an output driver and, more particularly, an output driver for an light emitting diode (LED).

### BACKGROUND

In communication systems, data may be optically transmitted through optical fibers. Electro-optical data converters are used for converting electrical data signals into optical signals. Differential non-return to zero (NRZ) formats are used at data rates of about 10 Gbps and beyond. Signal shaping techniques have to be applied for compensating deficiencies and inherent non-idealities of transmission media, as for example frequency dependent losses. In order to reduce power consumption, power supply levels are reduced.

Electro-optical data converters may include a driver and a light emitting semiconductor device as for example a VCSEL (Vertical Cavity Surface Emitting Laser) diode. VCSELs are often used as light emitting semiconductor devices. A VCSEL's circular beam is easily coupled with a fiber. This is mainly due to the characteristic of VCSEL diodes as a surface emission rather than edge emission device and they are known for their excellent power efficiency and durability. Accordingly, VCSEL diodes are widely used in low cost optical transmission systems. However, in high data rate transmission systems, the VCSEL diodes show some drawbacks. For the typical driving circuits, the VCSEL diodes represent a significantly high capacitance and the asymmetric turn on and turn off behavior often results in asymmetric optical eye plots. In order to optimize the bit error rate of the optical transmission link, it is desired to maximize the horizontal and vertical opening of the optical eye plot, i.e. to make the optical eye plot more symmetric. Existing VCSEL drivers therefore introduce output current peaking for steeper optical edges and a threshold adjustment capability in order to correct the eyes crossing point. Both enhancements increase the eye opening, but they fail to render the optical output eye more symmetric. A symmetric optical output eye represents the optimal solution for maximization of vertical and horizontal eye opening thereby minimizing the bit error rate. Theoretical and experimental studies have shown that symmetric optical eyes can be achieved by driving the VCSEL diode with a pre-distorted current signal showing single-sided or asymmetric current peaking. Such a solution is for example described in “A 20 Gb/s VCSEL Driver with Pre-Emphasis and Regulated Output Impedance in 0.13 μm CMOS, by D. Kucharski, Y. Kwark, D. Kuchta et al. This prior art solution superimposes a current peak to the tail current of the output driver, thereby creating an undershoot on its output signal. Both, the width and the height of the undershoot are fixed. The width of the undershoot is limited to the bit width of the input signal. By superimposing the peak current to the driver's tail current the output common mode and the crossing point of the output eye are shifted. Due to its single-sided and fixed peak value implementation, this solution does not allow a flexible adjustment to accommodate different data rates, different VCSEL diode parameters and to compensate the influence of the transmission media and the optical sub assembly.

FIG. 1 shows a circuit diagram of driver circuit for driving a VSCEL diode. An input stage comprises a differential pair of bipolar diodes Q1 and Q2. They are configured to receive differential input signal VIN with their base inputs INp, INn. The input stage further comprises resistor loads RL1, RL2 coupled to respective collectors of transistors Q1, Q2. Furthermore, there is current source coupled to the emitters of both transistors Q1, Q2 defining a tail current I1 through the differential pair. The collectors of transistors Q1, Q2 of the input differential pair provide an output signal VIN2 which is fed to an output stage which also comprises a differential pair of bipolar transistors Q3, Q4. The output stage also comprises resistor loads RL3, RL4 and a current source 12. The output voltage VOUT at the collectors (output nodes OUTn, OUTp) of the differential pair Q3, Q4 may then be used to drive the light VCSEL. The output current IOUT is the difference of the currents I3 and I4 through transistors Q3 and Q4. In a simplified equation, the output current IOUT can be defined as:

$$IOUT = I 2 \cdot tanh ( \frac{VIN 2}{2 VT} ) \qquad ( 1 )$$

where VT is the temperature voltage VT=k T/e with T being the absolute temperature and e the elementary charge. The output voltage can then be determined as:

$$VOUT = RL \cdot IOUT = RL \cdot I 2 tanh ( \frac{VIN 2}{2 VT} ) \qquad ( 2 )$$

With RL=RL3=RL4. This means that VOUT is a non-linear function of VIN2. However, as long as the input voltage swing of VIN2 exceeds approximately two times VT, the tail current I2 is completely switched from one branch (e.g. Q3) of the differential pair Q3, Q4 to the other side (e.g. Q4). Only for this condition VIN>2 VT, the output voltage VOUT approximates a linear function of I2, i.e. VOUT=RL*I2.

FIG. 2 shows another prior art driving stage. This driving stage differs from the one in FIG. 1 in that an additional differential pair Q5, Q6 is coupled in parallel to the differential pair Q3, Q4. The differential pair Q3, Q4 also receives VIN2 as input voltage from the input stage. The output current IOUT is now superimposed of currents IOUT3,4=IQ3−IQ4 and IOUT5,6=IQ5−IQ6. The result is an overshoot current generated at every edge of signal VIN2. The output voltage VOUT also shows the overshoot. The overshoot height and width may be controlled by filter elements RE5, RE6 and CE as well as the magnitude of current I3. Therefore, the circuit of FIG. 2 can be regarded as a pre-emphasis output driver, which may be used for compensating losses of transmission lines. However, since this superimposed output driver operates in limiting mode (i.e. VIN2>2 VT), the output signals show for ex-ample undesired common mode ripple VOUT,CM=(VOUTp+VOUTn)/2 at the output terminals OUTp, OUTn, where VOUTp is the voltage at node OUTp and VOUTn the voltage at node OUTn. This is due to a high frequency ripple at the emitter nodes VE2, VE3. This ripple converts into a common mode voltage ripple at the output nodes caused by the finite input impedances of the current sources 12 and 13, which are indicated with ZI2, ZI3. The common-mode ripple causes increased EMI which may adversely affect system requirements. Furthermore, the capacitive loading of the output terminals is increased as two differential pairs of transistors are coupled to the input stage. This aspect decreased the achievable bandwidth and therefore the maximum data rate.

### SUMMARY

Accordingly, an apparatus for driving a light emitting semiconductor device is provided. In one aspect of the invention, the apparatus comprises an input stage which is configured to receive a first input signal with a first differential pair of bipolar transistors and a second input signal with a second differential pair of bipolar transistors. The input stage is further configured to provide a pre-driver output signal being a superposition of the first input signal and the second input signal.

The apparatus may also comprise an output stage. The output stage may also be configured to drive the light emitting semiconductor device in response to the pre-driver output signal. The output stage may feed an output current to the light emitting semiconductor device in response to the pre-driver output signal. The output stage may comprise a third differential pair of bipolar transistors adapted to receive the pre-driver output signal of the input stage. In one aspect of the invention, the input stage may be configured to pre-distort the pre-driver output signal so as to compensate a distortion of the output stage. This aspect provides that an output signal of the output stage for driving the light emitting semiconductor device is a linear function of the pre-driver output signal. This reduces signal distortion of the driving signal for the light emitting semiconductor device.

The first and the second differential pair of bipolar transistors of the input stage may be coupled to degeneration resistors. This provides that the pre-driver output signal is a linear function of the first input signal and the second input signal, except the pre-distortion applied for compensating the distortion of the output stage. The pre-driver should then be adapted to pre-distort the input signal in a manner which is the inverse function of the distortion of the output stage. The first and the second differential pair of bipolar transistors of the input stage may therefore be coupled to a transistor load. The transistor load may be bipolar transistors. The load may be a diode load. The diode load may then be a transistor diode load, i.e. for example bipolar transistors in diode coupled configuration. The load may also be transistors in a common base structure. The load transistors may then be coupled with their bases to a common reference voltage level. The first and second differential pair may share the same load. The diode load or transistor (diode or common base) load can then serve to provide an appropriate pre-distortion. These aspects of the invention provide a trans-linear driver topology. The degeneration resistors coupled to the differential pairs of the input stage serve to establish a linear relationship between the output current of the input stage and the first and the second input voltages. Furthermore, the transistor load (e.g. diode coupled or in common base structure) coupled to the differential pairs, provides that the input voltage for the output stage is pre-distorted. Pre-distorting provides an overall linear relationship between the input signals to the input stage and the output signals (output voltage and/or output currents) of the output stage. The apparatus according to these aspects of the invention has less distortion and higher versatility than prior art devices.

The first input voltage and the second input voltage may advantageously be generated in a specific buffer stage for compensating negative line properties or non-ideal characteristics of the light emitting semiconductor device. The apparatus may then further comprise a delay buffer for delaying a driving signal for the light emitting semiconductor device. The delay buffer may be configured to generate the first input signal as a delayed version of the driving signal. The buffer stage may also comprise a pulse generation stage which is coupled in parallel to the delay buffer and adapted to selectively produce positive and negative pulses. Theses pulses may advantageously start concurrently with respective positive and negative edges of the first input signal. The pulses may then be used as the second input signal. The first input signal and the second input signal may then be fed to the first and second differential pair of the input stage. Accordingly, an apparatus according to these aspects of the invention is capable of generating over- and undershoot having a completely independent adjustment of peak width and height for both, the over- and the undershoot. The apparatus may therefore include a wave shaping circuitry which may comprise two major building blocks, the over- and undershoot generating stage (pulse generation stage) and a delay buffer connected in parallel to the pulse generation stage. The delay buffer is adapted to apply basically the same signal delay to the input signal as the pulse generation stage, such that the pulses produced by the pulse generation stage occur concurrently with the edges of the of the input signal. The main purpose of the delay buffer consists in delaying the input signal, such that a predetermined phase relationship between the output signal of the delay buffer (first input signal) and the output signal of the pulse generation circuit (second input signal) is established. The delay buffer can also be used to adjust the level of the input signal. The driving signal may have a substantially rectangular alternating waveform. The output of both stages (the delay buffer and the pulse generation stage) are superimposed, which may consist in a summing operation of the two output signals (e.g. voltages or currents) to represent the final output signal. The pulse generation stage may be adapted to produce short peaks with a controlled width and a controlled height at every edge of the input signal and falls back to zero in-between the peaks. This embodiment may preferably be used for driving VCSEL. However, it may also be advantageously applied to other kinds of semiconductor light emitting devices. A technology for implementing the present invention may be a bipolar or BICMOS technology.

In an embodiment, the apparatus may comprise a low impedance driving stage coupled between the input stage and the output stage for buffering the pre-driver output signal of the input stage. The output stage is then decoupled from the input stage, which provides an improved performance. The buffer or low impedance driving stage may comprise bipolar transistors coupled as emitter followers so as to serve as the low impedance driving stage and a level shifter. The distortion of the second input voltage may then further be reduced by the gain of the bipolar transistors. Furthermore, the level shift can provide more voltage headroom at the output terminals of the output stage. This allows lower supply voltage levels to be used for the apparatus.

In an aspect of the invention, a method of driving a light emitting semiconductor device is provided. A pre-driver output signal of a differential pair of bipolar transistors of an input stage may be pre-distorted so as to compensate a distortion of an output stage. The pre-distorted pre-driver output signal may then be applied (or fed) to the output stage for driving the light emitting semiconductor device. This provides that the output signals of the output stage can be a linear function of the input signal of the input stage. Pre-distortion may be provided by using a diode load, in particular a transistor diode load for a differential pair of bipolar transistors in the input stage. The output stage may then also include a differential pair of bipolar transistors. Degeneration resistors may also be used in the input stage.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF DRAWINGS

For a more complete understanding of the present invention, and the advantages thereof, reference is now made to the following descriptions taken in conjunction with the accompanying drawings, in which:

FIG. 1 shows a simplified circuit diagram of a prior art driver;

FIG. 2 shows another simplified circuit diagram of a prior driver;

FIG. 3 shows a basic block diagram of an embodiment of the invention;

FIG. 4 shows the block diagram of FIG. 3 in more detail;

FIG. 5 shows a simplified circuit diagram of an embodiment of the invention;

FIG. 6 shows a simplified circuit diagram of another embodiment of the invention; and

FIG. 7 shows a simplified circuit diagram of still another embodiment of the invention.

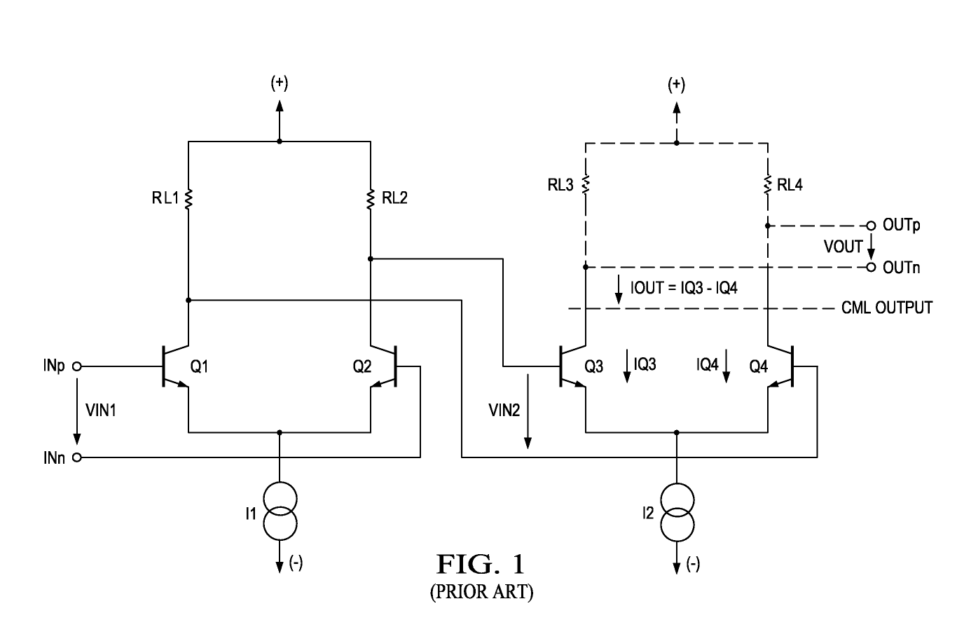

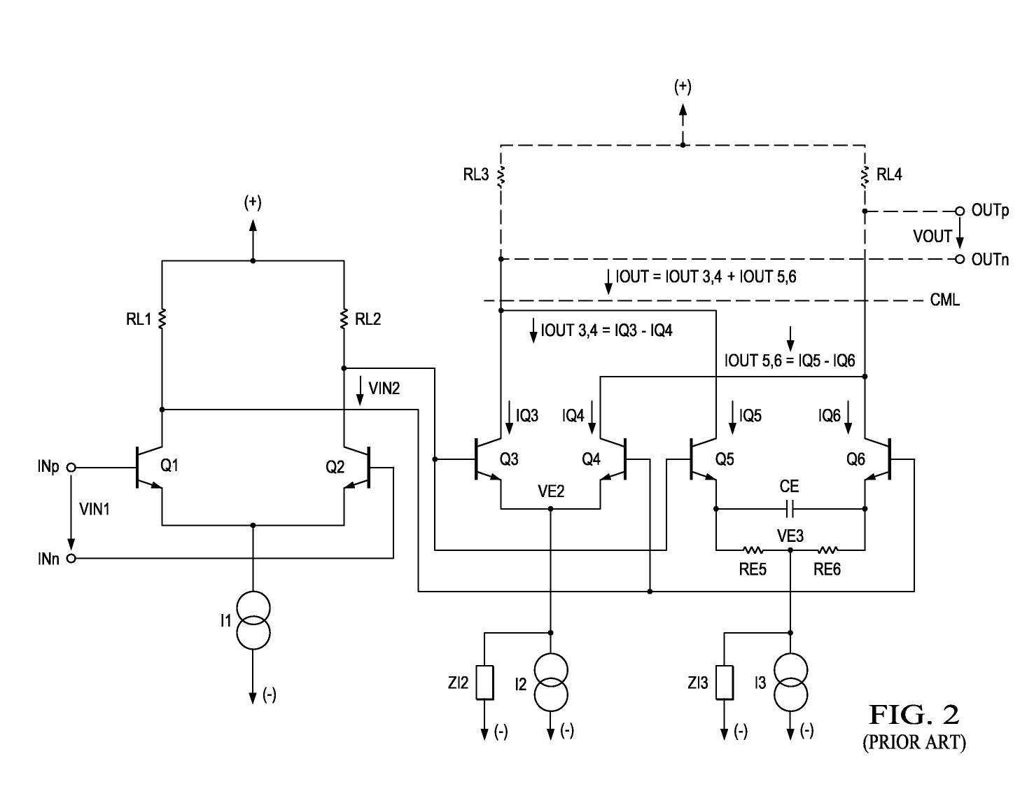

### DETAILED DESCRIPTION

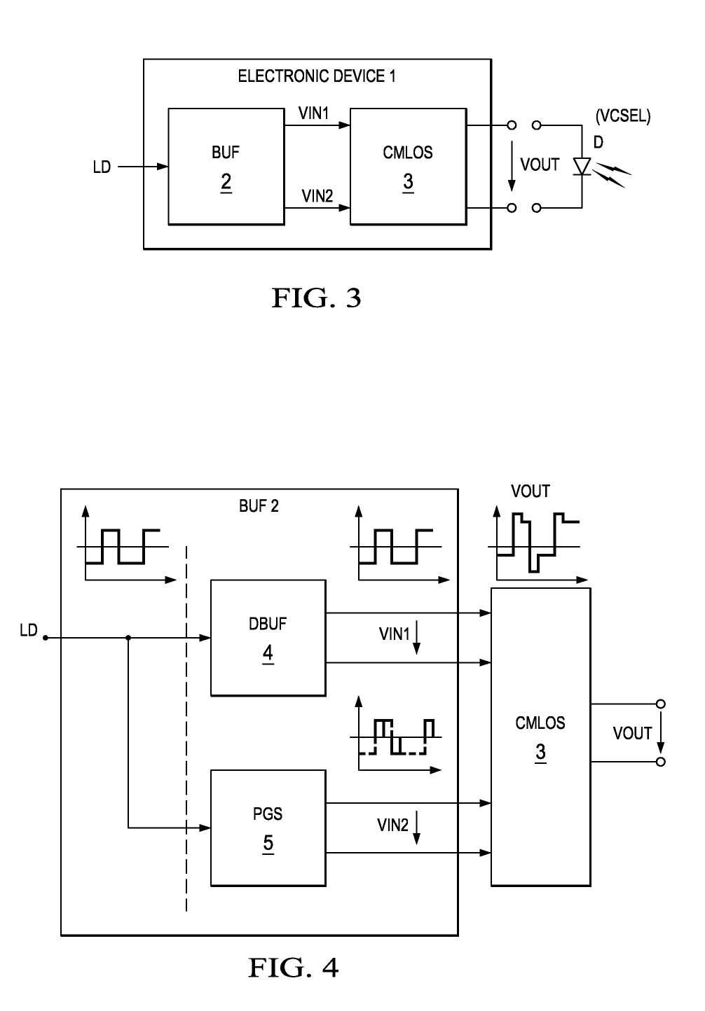

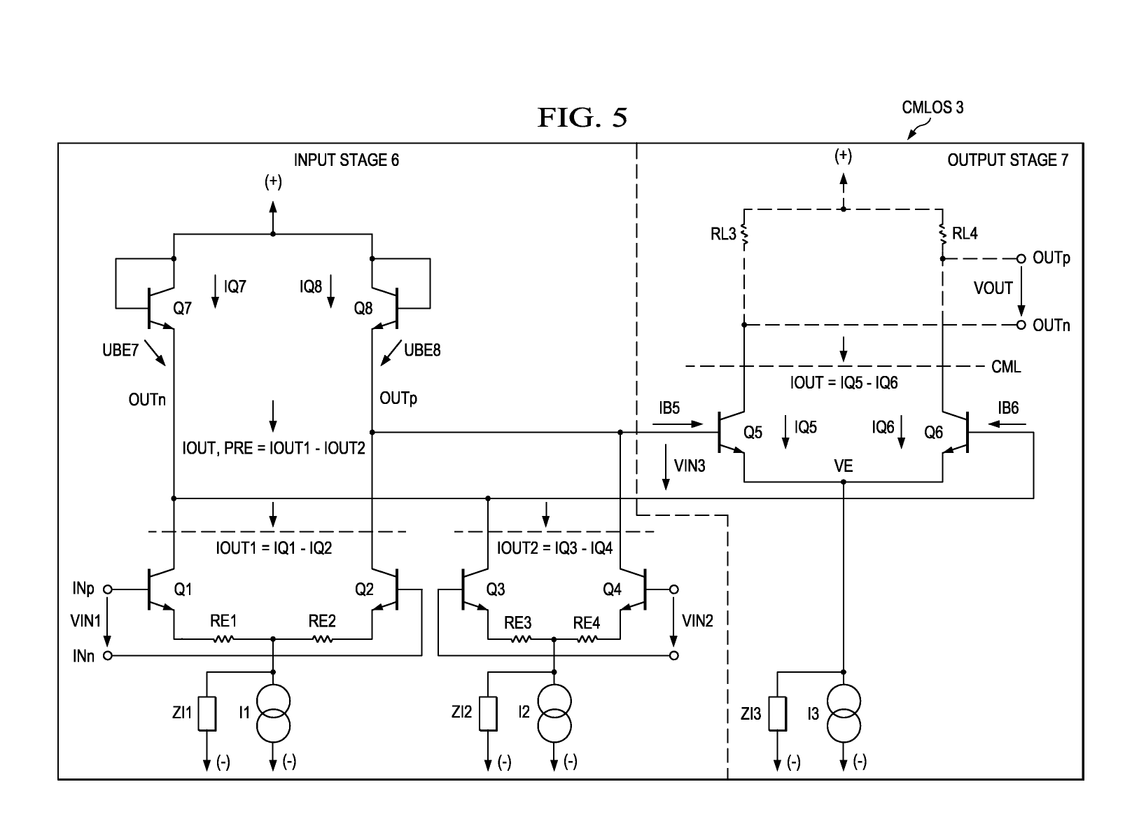

FIG. 3 shows a simplified and basic block diagram of an embodiment of the invention. The integrated circuit (IC) 1 may be one or more integrated semiconductor circuits configured in accordance with aspects of the invention. The buffer BUF 2 receives a driving signal LD for driving a light emitting semiconductor device D. Although a diode D is shown, the light emitting semiconductor device may be any other light emitting semiconductor device, as for example a VCSEL (Vertical Cavity Surface Emitting Laser). The buffer receives the driver signal LD and produces two output signals VIN1 and VIN2 which are fed to current mode logic output stage CMLOS 3. Some embodiments of the current mode logic output stage CMLOS 3 are explained below with reference to FIGS. 5, 6 and 7. Although some signals, as for example VIN1, VIN2, are shown as single-ended signals and others as fully differential signals VOUT in the embodiments of the invention, either single-ended or fully differential signals may be used.

FIG. 4 shows a block diagram of an embodiment of buffer 2 shown in FIG. 3. A delay buffer DBUF 4 is coupled in parallel to a pulse generation stage PGS 5. The basic functionality of the shown architecture can be derived from the waveforms indicated at the input node LD and the respective outputs VIN1, VIN2 (fully differential signals) of the delay buffer DBUF 4 and the pulse generation stage PGS 5, as well as at the output VOUT of current mode logic output stage CMLOS 3. The input signal at the input node LD is fed to the delay buffer DBUF 4 and the pulse generation stage PGS 5. The delay buffer DBUF 4 basically applies a delay to the input signal that compensates the delay the input signal undergoes in the pulse generation stage PGS 5. The pulse generation stage PGS produces positive and negative pulses concurrently with the rising and falling edges of the output signal VIN1 of the delay buffer DBUF 4. The output signal VIN1 of the delay buffer DBUF 4 is indicated as a doted line in the waveform diagram at the output VIN2 of the pulse generation stage PGS. The delayed input signal VIN1 received at the output of the delay buffer DBUF 4 and the pulse signal VIN2 generated by the pulse generation stage PGS are fed to current mode logic output stage CMLOS 3. The current mode logic output stage CMLOS 3 performs a superposition of the two input signals VIN1 and VIN2. This superposition may be a summing such that the combined output signal VOUT shows the desired over- and undershoot pulses at the rising and falling edges of the delayed input signal VIN1. The height and the width of the over- and undershoot pulses VIN2 can be arbitrarily defined within the pulse generation stage PGS.

FIG. 5 shows a simplified circuit diagram of an embodiment of a current mode logic output stage CMLOS 3. The current mode logic output stage CMLOS 3 comprises an input stage 6 and an output stage 7. The input stage may also be referred to as pre-driver. The input stage 6 includes two differential pairs of bipolar transistors: a first differential pair of bipolar transistors Q1, Q2 and second pair of bipolar transistors Q3, Q4. The emitters of the transistors Q1, and Q2 of the first differential pair are coupled to degeneration resistors RE1, and RE2, respectively. The other sides of degeneration resistors RE1, RE2 are coupled together and to tail current source I1. The finite impedance of tail current source I1 is indicated as ZI1 In another embodiment, two current sources may be used in combination with a single resistor RE=RE1+RE2 between the emitters. The collectors of transistors Q1, Q2 of the first differential pair are coupled to diode loads. In this embodiment, the diode loads are implemented with diode coupled bipolar transistors Q7 and Q8. In a different embodiment, a common base structure may be used, where the bases of transistors Q7, Q8 are coupled to a common reference voltage. The emitters of transistors Q7, Q8 are coupled to the collectors of the transistors Q1, Q2 of the first differential pair. Bases and collectors of load transistors Q7, Q8 are coupled together (diode coupled) and to supply voltage level. The first differential pair receives a first input voltage VIN1. The first differential pair has two output nodes OUT1n, and OUT1p which have a voltage difference VIN3.

The input stage 6 also includes a second differential pair of bipolar transistors Q3, and Q4. The emitters of the transistors Q3, and Q4 of the second differential pair are coupled to degeneration resistors RE3, and RE4, respectively. The other sides of degeneration resistors RE3, RE4 are coupled together and to tail current source 12. The finite impedance of tail current source 12 is indicated as ZI2. The collectors of transistors Q3, Q4 of the second differential pair are coupled to diode loads. In this embodiment, the second differential pair Q3, Q4 is coupled to the same loads as the first differential pair Q1, Q2, The first differential pair Q1, Q2 and the second differential pair Q3, Q4 share the same load. This load is a diode load, in particular a load which is implemented with two diode coupled bipolar transistors. The load may also be implemented with a common-base structure. The load transistors may then be coupled with their bases to a common reference voltage.

The output stage 7 includes a third differential pair of bipolar transistors Q5, Q6. The emitters of the bipolar transistors Q5, Q6 of the third differential stage are directly and commonly coupled to tail current source 13. The finite impedance of this current source is indicated as ZI3. The loads of output stage 7 are two load resistors RL3 and RL4 in this embodiment which are coupled to the collectors of bipolar transistors Q5, Q6 of the output stage 7. In an advantageous aspect, there may be a different load, which may not be resistive. The output stage 7 may especially used for driving currents through light emitting semiconductor devices. For example, the output stage may be used for driving VCSELs. The load may then be a VCSEL instead of the shown resistor (s). The output nodes OUTp, OUTn are the output nodes of the third differential pair Q5, Q6. The voltage difference between the output nodes OUTn, OUTp of the third differential stage is the output voltage VOUT, which may be used for driving a light emitting semiconductor device as for example a VCSEL.

The driver topology shown in FIG. 5 overcomes deficiencies of prior art driver topologies. It uses a trans-linear operation mode and is configured to provide versatile output waveform shaping. The degeneration resistors RE1, RE2 at the emitters of the first differential pair Q1, Q2 provide linear relationship between the output current IOUT1 of the first differential pair and the first input voltage VIN1 as long as the first input voltage VIN1 is smaller than the maximum voltage drop across either of the degeneration resistors RE1, RE2:

$$IOUT 1 = \frac{VIN 1}{RE} \qquad ( 3 )$$

with VIn1<<RE*I1 and RE=RE1=RE2. The second differential pair Q3, Q4 in parallel to the first differential pair is also emitter-degenerated through emitter resistors RE3, RE4. This provides that also the output current IOUT2 of the second differential pair linearly depends on the second input voltage VIN2:

$$IOUT 2 = \frac{VIN 2}{RE} \qquad ( 4 )$$

with VIN2<<RE*I2 and RE=RE3=RE4. The resulting input stage current (or pre-driver) current IOUT,PRE is then:

IOUT,PRE=IOUT1+IOUT2. (5)

And the average input stage current IOUT,PRE,AVG is

$$IOUT , PRE , AVG = \frac{IOUT 1 + IOUT 2}{2} = \frac{I 1 + I 2}{2} \qquad ( 6 )$$

Transistors Q7, Q8 are coupled to serve as loads for the input stage. These transistor diodes generate a pre-distorted input voltage VIN3 (pre-driver output voltage) for the output stage 7. The result is a linear conversion of the current IOUT,PRE of the input stage into the current IOUT=IQ5−IQ6 of the output stage. The output current IOUT in the output stage is a non-linear function of the input voltage VIN3 of the output stage:

$$VOUT = RL \cdot IOUT = RL \cdot I 3 \cdot tanh ( \frac{VIN 3}{2 VT} ) \qquad ( 7 )$$

with RL=RL3=RL4. VIN3 obeys the following relationship:

VIN3=(VBE+ΔV)−(VBE−ΔV) (8)

with VBE7=VBE8=VBE and ΔV being the input voltage change. There is further the relationship:

$$VBE = VT \cdot In ( \frac{IOUT , PRE , AVG}{IS} ) \qquad ( 9 )$$

which can be used in the previous equation. This results in

$$\begin{matrix}VBE + Δ V = VT \cdot In ( \frac{IOUT , PRE , AVG + Δ I}{IS} ) & ( 10 ) \\ VBE - Δ V = VT \cdot In ( \frac{IOUT , PRE , AVG - Δ I}{IS} ) & ( 11 )\end{matrix}$$

where ΔI is the output current change corresponding to ΔV. This provides that

$$\frac{Δ V}{VT} = \frac{VIN 3}{2 VT} = \frac{1}{2} In ( \frac{1 + ( \frac{Δ I}{IOUT , PRE , AVG} )}{1 - ( \frac{Δ I}{IOUT , PRE , AVG} )} ) \qquad ( 12 )$$

The inverse function of the hyperbolic function is:

$$artanh ( x ) = \frac{1}{2} In ( \frac{1 + x}{1 - x} ) \qquad ( 13 )$$

with x=ΔI/IOUT,PRE,AVG. This provides that the output voltage is a linear function of the first input voltage VIN1 and the second input voltage VIN2, since IOUT1 and IOUT2 are linear functions of the input voltages VIN1 and VIN2:

$$\begin{matrix}VOUT = RL \cdot I 3 \cdot tanh ( artanh ( x ) ) = RL \cdot Δ I \cdot ( \frac{I 3}{IOUT , PRE , AVG} ) & ( 14 ) \\ and & \\ IOUT = \frac{VOUT}{RL} = Δ I \cdot ( \frac{I 3}{IOUT , PRE , AVG} ) & ( 15 )\end{matrix}$$

The last equation shows that IOUT is linearly controlled through the superimposed current IOUT,PRE,AVG. The input stage provides a pre-distortion being the inverse function of the distortion of the output stage. This can be implemented with a load in the input stage being of the same type as the input devices of the output stage. Therefore, versatile signal shaping of the output signal is available by merely applying arbitrary driving signals LD to the apparatus. The embodiments of the invention provide that overlay input voltages VIN1, VIN2 will always drive the output driver in linear mode. Transistors Q5, Q6 of the third differential pair in the output stage 7 are never completely turned off or reversely biased. This minimizes signal distortion and common mode ripple. Furthermore, the capacitive load for the input stage 6 is smaller than for prior art drivers. Therefore, the driver according to the invention supports larger bandwidths and higher data rates.

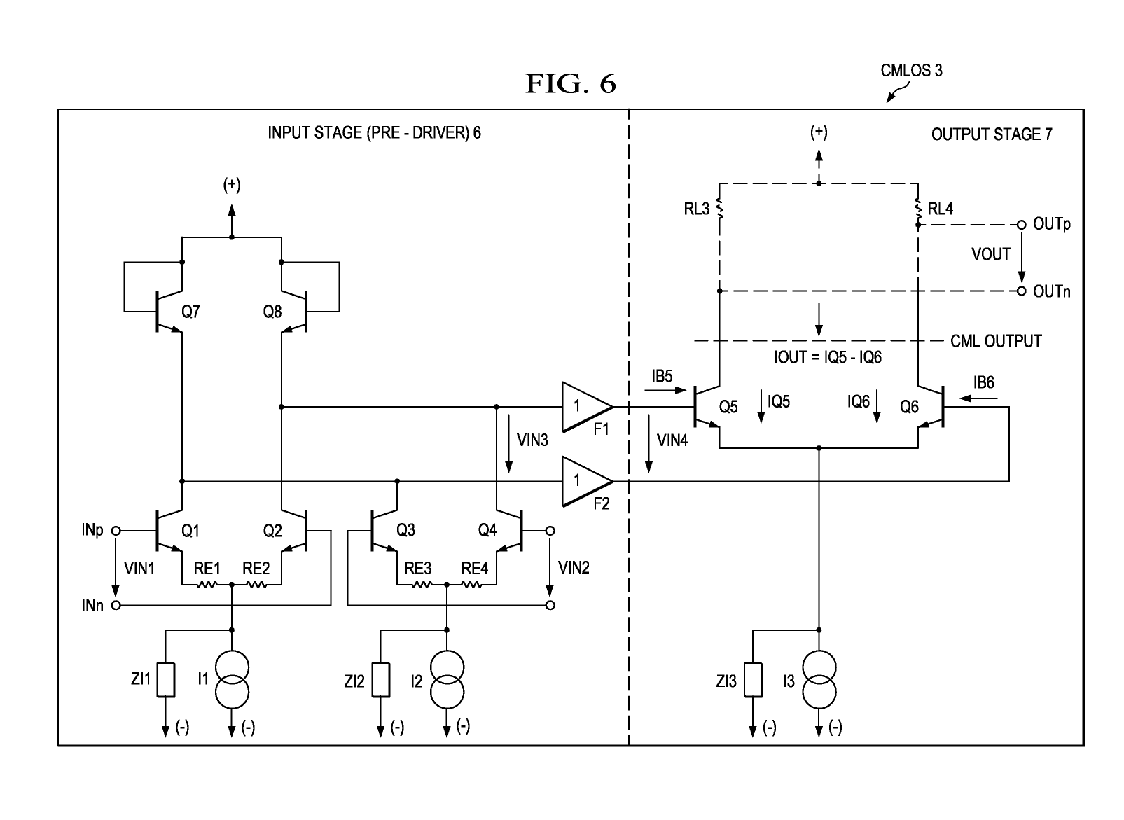

FIG. 6 shows a simplified circuit diagram of an embodiment of the invention. The current mode logic output stage CMLOS 3 shown in FIG. 6 is basically similar to the circuitry shown in FIG. 5. However, there are two low impedance buffers F1, F2 inserted between the input stage and the output stage. Buffers F1, F2 generally provide that the output stage is decoupled from the input stage. High ohmic inputs of the buffers F1, F2 reduce distortion, whereas low ohmic outputs of buffers improve driving characteristics for the output stage 7. This can improve driving performance.

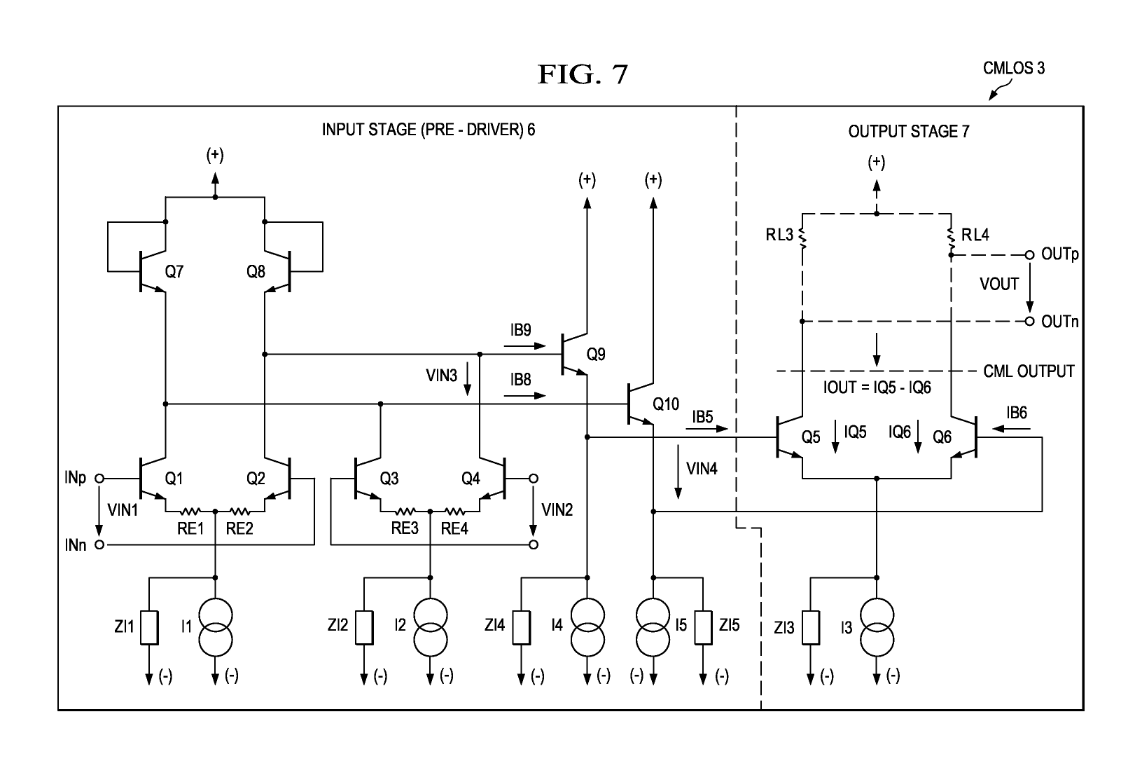

FIG. 7 shows an embodiment of current mode logic output stage CMLOS 3, where the low impedance buffers F1, F2 of FIG. 6 are implemented with two emitter followers. The emitter followers are implemented with bipolar transistors Q9, Q10. Current sources I4, I5 are coupled to the emitters of transistors Q9, Q10. The finite input impedance of the current sources I4, I5 are represented by impedances ZI4 and ZI5. The collectors of transistors Q9, Q10 are coupled to supply voltage level. The output voltage VIN3 is now fed to the bases of transistors Q9, Q10. The emitter of transistor Q10 is coupled to the base of transistor Q6 of the third differential pair of the output stage. The emitter of transistor Q9 is coupled to the base of transistor Q5 of the third differential pair of the output stage. The emitter followers Q9, Q10 perform an impedance transformation with respect to base currents IB5, IB6 of transistors Q5, Q6 of the output stage. The load currents of load transistors Q7, Q8 are reduced by the current gain β of the emitter follower transistors Q9, Q10 and the relationship of base currents IB8, IB9 of transistors Q8, Q9 and currents IB6, IB5 is as follows:

IB8=IB6/β (16)

IB9−IB5/β (17)

Distortion of the wave-shaped voltage VIN2 due to load currents IB5, IB6 is reduced by the current gain β. VIN3 is converted into a voltage VINI4 of identical shape by the emitter followers Q9, Q10. VIN4 drives the output stage 7. Therefore, the output currents IQ5, IQ6, IOUT can be increased without increasing the level of wave-shape distortion. Furthermore, a bias level shift between the pre-driver (input stage 6) and the output stage 7 is performed. This provides that the output stage 7 has a lower bias voltage level (at the bases of Q5, Q6) and can therefore be supplied with a lower supply voltage level for the same voltage headroom.

Having thus described the present invention by reference to certain of its preferred embodiments, it is noted that the embodiments disclosed are illustrative rather than limiting in nature and that a wide range of variations, modifications, changes, and substitutions are contemplated in the foregoing disclosure and, in some instances, some features of the present invention may be employed without a corresponding use of the other features. Accordingly, it is appropriate that the appended claims be construed broadly and in a manner consistent with the scope of the invention.

1. An apparatus comprising:
an input stage having:
a first differential pair of bipolar transistors including a pair of input terminal and a pair of output terminals, wherein the input terminals of the first differential pair receive a first input signal;
a pair of diode-connected transistors that each coupled between a supply rail and one of the output terminals of the first differential pair; and
a second differential pair of bipolar transistors including a pair of input terminal and a pair of output terminals, wherein the input terminals of the second differential pair receive a second input signal, and wherein the output terminals of the first differential pair are coupled to the output terminals of the second differential pair;
and
an output stage having a third differential pair of bipolar transistors that includes a pair of input terminals and a pair of output terminals, wherein the input terminals of the third differential pair are coupled to the output terminals of the first differential pair.

2. The apparatus of claim 1, wherein the first differential pair further comprises:
a first output terminal;
a second output terminal;
a first bipolar transistor that receives a first portion of the first input signal at its base and that is coupled to the first output terminal at its collector;
a second bipolar transistor that receives a second portion of the first input signal at its base and that is coupled to the second output terminal at its collector; and
a first set of resistors coupled in series with one another between the emitters of the first and second bipolar transistors.

3. The apparatus of claim 2, wherein the second differential pair further comprises:
a third bipolar transistor that receives a first portion of the second input signal at its base and that is coupled to the first output terminal at its collector;
a fourth bipolar transistor that receives a second portion of the second input signal at its base and that is coupled to the second output terminal at its collector; and
a second set of resistors coupled in series with one another between the emitters of the third and fourth bipolar transistors.

4. The apparatus of claim 3, wherein the pair of diode-connected transistors further comprises:
a first bipolar diode-connected transistor that is coupled between the supply rail and the first output terminal; and
a second bipolar diode-connected transistor that is coupled between the supply rail and the second output terminal.

5. The apparatus of claim 4, wherein the output stage further comprises:
a third output terminal;
a fourth output terminal;
a fifth bipolar transistor that is coupled to the first output terminal at its base and that is coupled to the third output terminal at its collector; and
a sixth bipolar transistor that is coupled between the second output terminal at its base, that is coupled to the emitter of the fifth bipolar transistor at its emitter, and that is coupled to the fourth output terminal at its collector.

6. The apparatus of claim 5, wherein the apparatus further comprises:
a first buffer that is coupled between the first output terminal and the base of the fifth bipolar transistor; and
a second buffer that is coupled between the second output terminal and the base of the sixth bipolar transistor.

7. The apparatus of claim 5, wherein the apparatus further comprises:
a first level shifter that is coupled between the first output terminal and the base of the fifth bipolar transistor; and
a second level shifter that is coupled between the second output terminal and the base of the sixth bipolar transistor.

8. An apparatus comprising:
an input buffer that receives a drive signal and generates a first input signal and a second input signal; and
a current mode logic output circuit including:
an input stage having:
a first differential pair of bipolar transistors including a pair of input terminal and a pair of output terminals, wherein the input terminals of the first differential pair are coupled to the input buffer so as to receive a first input signal;
a pair of diode-connected transistors that each coupled between a supply rail and one of the output terminals of the first differential pair; and
a second differential pair of bipolar transistors including a pair of input terminal and a pair of output terminals, wherein the input terminals of the second differential pair are coupled to the input buffer so as to receive a second input signal, and wherein the output terminals of the first differential pair are coupled to the output terminals of the second differential pair; and
an output stage having a third differential pair of bipolar transistors that includes a pair of input terminals and a pair of output terminals, wherein the input terminals of the third differential pair are coupled to the output terminals of the first differential pair.

9. The apparatus of claim 8, wherein the first differential pair further comprises:
a first output terminal;
a second output terminal;
a first bipolar transistor that receives a first portion of the first input signal at its base and that is coupled to the first output terminal at its collector;
a second bipolar transistor that receives a second portion of the first input signal at its base and that is coupled to the second output terminal at its collector; and
a first set of resistors coupled in series with one another between the emitters of the first and second bipolar transistors.

10. The apparatus of claim 9, wherein the second differential pair further comprises:
a third bipolar transistor that receives a first portion of the second input signal at its base and that is coupled to the first output terminal at its collector;
a fourth bipolar transistor that receives a second portion of the second input signal at its base and that is coupled to the second output terminal at its collector; and
a second set of resistors coupled in series with one another between the emitters of the third and fourth bipolar transistors.

11. The apparatus of claim 10, wherein the pair of diode-connected transistors further comprises:
a first bipolar diode-connected transistor that is coupled between the supply rail and the first output terminal; and
a second bipolar diode-connected transistor that is coupled between the supply rail and the second output terminal.

12. The apparatus of claim 11, wherein the output stage further comprises:
a third output terminal;
a fourth output terminal;
a fifth bipolar transistor that is coupled to the first output terminal at its base and that is coupled to the third output terminal at its collector; and
a sixth bipolar transistor that is coupled between the second output terminal at its base, that is coupled to the emitter of the fifth bipolar transistor at its emitter, and that is coupled to the fourth output terminal at its collector.

13. The apparatus of claim 12, wherein the input buffer further comprises:
a delay buffer that is coupled to the bases of the first and second bipolar transistors; and
a pulse generator that is coupled to the bases of the third and fourth bipolar transistors.

14. The apparatus of claim 13, wherein the apparatus further comprises:
a first buffer that is coupled between the first output terminal and the base of the fifth bipolar transistor; and
a second buffer that is coupled between the second output terminal and the base of the sixth bipolar transistor.

15. The apparatus of claim 13, wherein the apparatus further comprises:
a first level shifter that is coupled between the first output terminal and the base of the fifth bipolar transistor; and
a second level shifter that is coupled between the second output terminal and the base of the sixth bipolar transistor.

16. The apparatus of claim 13, wherein the apparatus further comprises a light emitting diode (LED) that is coupled between the third and fourth output terminals.
